(19) United States
(12) Patent Application Publication
(10) Pub. No.: US 2026/0152854 A1
(43) Pub. Date: Jun. 4, 2026

(54) METHOD FOR PREPARING A CURRENT BLOCKING LAYER AND AN LED CHIP

(71) Applicant: BEIJING NAURA MICROELECTRONICS EQUIPMENT CO., LTD., Beijing (CN)

(72) Inventor: Yanhui LIU, Beijing (CN)

(21) Appl. No.: 19/464,286

(22) Filed: Jan. 29, 2026

Related U.S. Application Data
(63) Continuation of application No. PCT/CN2024/108071, filed on Jul. 29, 2024.

(30) Foreign Application Priority Data
Aug. 4, 2023 (CN) 202310981305.4

(51) Int. Cl. C23C 16/505; C23C 16/40; C23C 16/52; H10H 20/01; H10H 20/812; H10H 20/816

(52) U.S. Cl. CPC C23C 16/505; C23C 16/402; C23C 16/52; H10H 20/01335; H10H 20/812; H10H 20/8162

(57) ABSTRACT

A method for preparing a current blocking layer includes fabricating a first SiO₂ thin film on a substrate using a first PECVD process, depositing a second SiO₂ thin film on the surface of the first SiO₂ thin film in situ using a second PECVD process. The first PECVD process uses high-frequency radio frequency power, the second PECVD process uses high-frequency and low-frequency dual-frequency radio frequency power, and the high-frequency radio frequency power used in the first PECVD process is lower than the high-frequency radio frequency power used in the second PECVD process.

### CROSS-REFERENCE TO RELATED APPLICATION

The present application is a continuation of International Application No. PCT/CN2024/108071, filed on Jul. 29, 2024, which claims priority to Chinese Patent Application No. 202310981305.4, filed with the China National Intellectual Property Administration on Aug. 4, 2023 and entitled “A Method For Preparing A Current Blocking Layer and An Led Chip”, which are incorporated herein by reference in their entirety.

### TECHNICAL FIELD

The present disclosure generally relates to the semiconductor technology field and, more particularly, to a method for preparing a current blocking layer and an LED chip.

### BACKGROUND

FIG. 1 is a schematic structural diagram of a conventional LED chip. As shown in FIG. 1, the LED chip, from bottom to top, includes a substrate 10, an N-type semiconductor layer 20, a multiple quantum well (MQW) layer 30, a P-type semiconductor layer 40, a conductive layer 50, a P-electrode 60 connected to the conductive layer 50, and an N-electrode 70 connected to the N-type semiconductor layer 20, and a current blocking layer 80 located between the P-type semiconductor layer 40 and the conductive layer 50 in the region corresponding to the P-electrode 60.

P-type carriers and N-type carriers recombine in the multiple quantum well layer 30 to generate photons. The N-type semiconductor layer 20, the multiple quantum well layer 30, and the P-type semiconductor layer 40 constitute the light-emitting functional layer of the LED chip. The current blocking layer 80 is generally a SiO₂ thin film, which prevents the current generated from the P-electrode 60 from diffusing towards the area directly below P-electrode 60 in the conductive layer 50, increasing the current density in other areas of the conductive layer 50. This reduces the blocking and absorption of light by the P-electrode 60, allowing for better extracting photons from the LED chip and improving the current distribution in the conductive layer 50, thereby alleviating the current crowding under the P-electrode 60 and increasing the internal quantum efficiency and light extraction efficiency of the LED chip. This needs the SiO₂ thin film to have a high dielectric constant (insulating property) and high density.

At present, SiO₂ thin films are mainly fabricated by plasma enhanced chemical vapor deposition (PECVD) process. Deposition at high radio frequency (RF) power and low RF frequency can improve the insulation and density of the SiO₂ thin film, but it can also damage the P-type semiconductor layer 40. If low RF power and high RF frequency are used for deposition to avoid damaging the P-type semiconductor layer 40, it will lead to a decrease in the insulation and density of the SiO₂ thin film.

### SUMMARY

In accordance with the disclosure, the current disclosure provides a method for preparing a current blocking layer including fabricating a first SiO₂ thin film on a substrate using a first PECVD process, depositing a second SiO₂ thin film on the surface of the first SiO₂ thin film in situ using a second PECVD process. The first PECVD process uses high-frequency RF power, the second PECVD process uses high-frequency and low-frequency dual-frequency RF power, and the high-frequency RF power used in the first PECVD process is lower than the high-frequency RF power used in the second PECVD process.

### BRIEF DESCRIPTION OF THE DRAWINGS

The accompanying drawings are incorporated into and constitute a part of this specification, illustrating embodiments consistent with the present disclosure and are used in conjunction with the description to explain the principles of the present disclosure. To more clearly illustrate the technical solutions of the embodiments of the present disclosure, the drawings needed for the description of the embodiments will be briefly introduced below. Obviously, for those skilled in the art, other drawings can be obtained based on these drawings without creative effort.

FIG. 1 is a schematic structural diagram of a conventional LED chip.

FIG. 2 is a schematic flowchart of a method for preparing a current blocking layer provided in one embodiment of the present disclosure.

FIG. 3 is a schematic flowchart of a method for preparing a current blocking layer provided in another embodiment of the present disclosure.

FIG. 4 is a schematic flowchart of a method for preparing a current blocking layer consistent with the present disclosure.

The realization of the objectives, functional features, and advantages of the present disclosure will be further explained in conjunction with the embodiments and with reference to the accompanying drawings. The accompanying drawings show specific embodiments of the present disclosure, which will be described in more detail below. These drawings and detailed descriptions are not intended to limit the scope of the concept of the present disclosure in any way, but rather to illustrate the concept of the present disclosure to those skilled in the art by referring to specific embodiments.

### DETAILED DESCRIPTION OF THE EMBODIMENTS

The exemplary embodiments will be described in detail herein, with examples illustrated in the accompanying drawings. When referring to the drawings below, unless otherwise indicated, the same numbers in different figures represent the same or similar elements. The embodiments described in the following exemplary embodiments do not represent all embodiments consistent with the present disclosure. Rather, they are merely some embodiments of apparatus and methods consistent with some aspects of the present disclosure as detailed in the claims.

It should be noted that, consistent with the present disclosure, the terms “comprise,” “include,” or any other variation thereof are intended to cover non-exclusive inclusion, so that a process, method, article, or apparatus that includes a series of elements not only includes those elements, but also includes other elements not explicitly listed, or elements inherent to such a process, method, article, or apparatus. Without further limitation, an element defined by the phrase “comprising one . . . ” does not exclude the presence of other identical elements in the process, method, article, or apparatus including that element. Furthermore, components, features, and elements with the same names in different embodiments of the present disclosure may have the same meaning or different meanings, and their specific meaning should be determined by their interpretation in that specific embodiment or further in conjunction with the context in that specific embodiment.

It should be further understood that the terms “comprising,” “including” indicate the presence of the described features, steps, operations, elements, components, items, types, and/or groups, but do not exclude the presence, occurrence, or addition of one or more other features, steps, operations, elements, components, items, types, and/or groups. The terms “or,” “and/or,” “including at least one of the following,” etc., as used in the present disclosure, may be interpreted as inclusive, or meaning any one or any combination. For example, “including at least one of: A, B, C” means “any one of the following: A; B; C; A and B; A and C; B and C; A and B and C,” and similarly, “A, B or C” or “A, B and/or C” means “any one of the following: A; B; C; A and B; A and C; B and C; A and B and C”. An exception to this definition only occurs when the combination of elements, functions, steps, or operations is inherently mutually exclusive in some way.

It should be understood that although the terms first, second, third, etc., may be used herein to describe various information, such information should not be limited to these terms. These terms are only used to distinguish information of the same type from each other. For example, without departing from the scope of the present disclosure, the first information could also be referred to as the second information, and similarly, the second information could also be referred to as the first information. Depending on the context, the singular forms “a,” “an,” and “the” used herein are intended to also include the plural forms, unless otherwise indicated by the context.

It should be understood that the terms “top,” “bottom,” “upper,” “lower,” “vertical,” “horizontal,” etc., indicating directional or positional relationships are based on the directional or positional relationships shown in the accompanying drawings, and are only for the convenience of describing the present disclosure and simplifying the description, and are not intended to indicate or imply that the described apparatus must have a specific orientation, be constructed and operated in a specific orientation, and therefore should not be construed as a limitation of the present disclosure.

Before preparing the current blocking layer consistent with the present disclosure, light-emitting functional layers can be formed on the surface of the substrate.

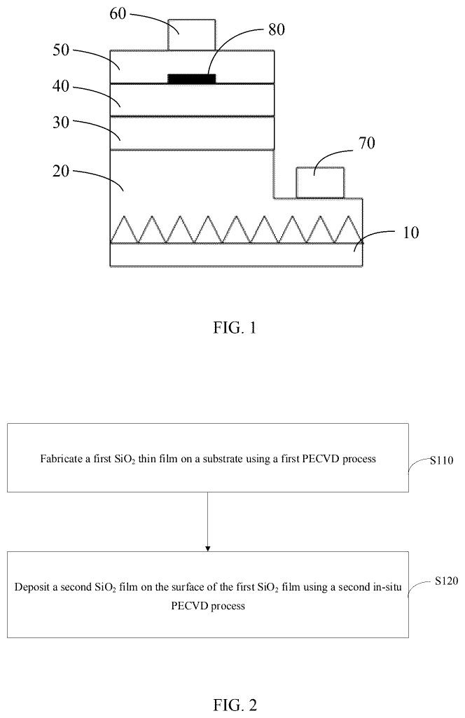

In some embodiments, as shown in FIG. 1, the substrate 10 can be made of sapphire, silicon carbide, silicon, silicon-containing substrate, epitaxial silicon substrate, silicon-on-insulator (SOI), lithium niobate, or diamond.

The light-emitting functional layer may include an N-type semiconductor layer 20, a multi-quantum well layer 30, and a P-type semiconductor layer 40, formed sequentially on the surface of the substrate 10 from bottom to top. The P-type carriers in the P-type semiconductor layer 40 and the N-type carriers in the N-type semiconductor layer 20 recombine in the multi-quantum well layer 30 to generate photons; therefore, the multi-quantum well layer 30 is also the light-emitting layer. The current blocking layer of the present disclosure is located on the surface of the P-type semiconductor layer 40.

For example, the substrate 10 may be a conventional patterned sapphire substrate (CPSS), the N-type semiconductor layer 20 may be N-GaN, and the P-type semiconductor layer 40 may be P-GaN.

FIG. 2 is a schematic flowchart of a method for preparing a current blocking layer consistent with the present disclosure. The method includes the following.

At S110, a first SiO₂ thin film is fabricated on the substrate by a first PECVD process.

Plasma Enhanced Chemical Vapor Deposition (PECVD) is a process of preparing thin films on substrates by using plasma formed by glow discharge to influence the deposition process during low-pressure chemical vapor deposition.

The first PECVD process uses high-frequency RF power, and the high-frequency RF power used in the first PECVD process is lower than that of a second PECVD process. That is, the first SiO₂ thin film is prepared using a first PECVD process with low RF power and high RF frequency (HF), which can avoid damage to the surface of the P-type semiconductor layer caused by high-energy particles generated by the conventional low RF frequency (LF) preparation process.

In some embodiments, the reaction gases used in the first PECVD process include SiH₄, N₂O, and N₂.

Consistent with the present disclosure, SiH₄, N₂O, and N₂ are used as reaction gases, in which N₂ is used as diluent gas, and the Si source provided by SiH₄ and the O source provided by N₂O react to form SiO₂. The first SiO₂ thin film can be formed on a localized area of the top surface of the P-type semiconductor layer of the substrate. As mentioned above, the conventional PECVD process of high RF power and low RF frequency for fabricating SiO₂ thin films may damage the P-type semiconductor layer 40. This is because the plasma generated by the power supply of low RF frequency has a lower density, resulting in a longer free path for the particles and a lower probability of collisions between the particles. The bombardment energy of the particles on the P-type semiconductor layer 40 is large, thereby causing damage to the surface of the P-type semiconductor layer.

In some embodiments, in the first PECVD process, the high-frequency RF power is 10-50 W, and the high-frequency RF frequency is 10-60 MHz.

In the first PECVD process consistent with present disclosure, high-frequency RF power is used, and the high-frequency RF power used in the first PECVD process is lower than that in the second PECVD process, which can avoid damage to the surface of the P-type semiconductor layer caused by ion bombardment. For example, the high-frequency RF power can be 10-50 W, and the high-frequency RF frequency can be 10-60 MHz. In one embodiment, the high RF frequency (HF) can be a commonly used RF frequency of 13.56 MHz.

In one embodiment, in the process of preparing the first SiO₂ thin film, the flow rate of SiH₄ can be 5-35 sccm (standard cubic centimeters per minute), the flow rate of N₂O can be 500-1700 sccm, and the flow rate of N₂ can be 800-2400 sccm. For example, the chamber can be evacuated to achieve a base vacuum (e.g., 3 mT-5 mT, “mT” here means millitorr), the deposition temperature range for the first SiO₂ thin film is set to 100° C.-200° C., and the deposition reaction is carried out using SiH₄, N₂O, and N₂ at the above flow rates as reaction gases, under the conditions of a high-frequency RF frequency of 13.56 MHz and a high-frequency RF power of 10 W-50 W. The chamber pressure range during the deposition of the first SiO₂ thin film can be controlled within 400 mT-1200 mT. The thickness of the first SiO₂ thin film can be 500 Å-2000 Å.

At S120, a second SiO₂ film is deposited on the surface of the first SiO₂ film using a second in-situ PECVD process.

After the first SiO₂ thin film is deposited on the P-type semiconductor layer 40, a second PECVD process using high-frequency (HF)-low-frequency (LF) dual-frequency is employed in-situ to deposit a second SiO₂ thin film on the surface of the first SiO₂ thin film. That is, the second PECVD process uses high-frequency and low-frequency dual-frequency RF power, and the high-frequency RF power used in the second PECVD process is higher than that of the first PECVD process.

The high-frequency part of the second PECVD process can obtain a higher density plasma to improve the deposition efficiency and thickness uniformity of the second SiO₂ thin film, and the low-frequency part can enhance the bombardment of the first SiO₂ thin film and second SiO₂ thin film, improving the film density. The first SiO₂ thin film can act as a protective layer to prevent high-energy particles generated by the low-frequency part from directly bombarding and damaging the P-type semiconductor layer.

The current blocking layer fabricated in the embodiment of the present disclosure not only has high insulation and density, but also avoids damage to the P-type semiconductor layer.

In some embodiments, the reaction gases used in the second PECVD process include SiH₄, N₂O, and N₂. Using SiH₄, N₂O, and N₂ as reaction gases, a second PECVD process using high-frequency-low-frequency dual-frequency in-situ is employed to deposit a second SiO₂ thin film on the surface of the first SiO₂ thin film.

In some embodiments, in the second PECVD process, the high-frequency RF power is 200-700 W, and the high-frequency RF frequency is 10-60 MHz.

In the dual-frequency process, the high-frequency part can obtain a higher density plasma to improve the deposition efficiency and thickness uniformity of the second SiO₂ film. For example, the high-frequency RF frequency can be the commonly used 13.56 MHz RF frequency. However, SiO₂ film formed only by high frequency has poor density, which affects the insulation properties of the SiO₂ film. To solve this problem, in some embodiments, in the second PECVD process, the low-frequency RF power is 80-300 W, and the low-frequency RF frequency is 100-500 KHz. The low-frequency part in the embodiment of the present disclosure can enhance the bombardment of the first SiO₂ film and second SiO₂ film, improving the film density, which also enhances the insulation properties of the film. The first SiO₂ film can act as a protective layer to prevent high-energy particles generated by the low-frequency part from directly bombarding and damaging the P-type semiconductor layer. In one embodiment, the low-frequency RF power and RF frequency can be 80-300 W and 100-500 KHz, respectively.

In one embodiment, in the process of preparing the second SiO₂ film (i.e., the second PECVD process), the flow rate of SiH₄ can be 10-60 sccm, the flow rate of N₂O can be 1000-3000 sccm, and the flow rate of N₂ can be 900-2800 sccm. For example, using SiH₄, N₂O, and N₂ at the above flow rates as reaction gases, the deposition reaction is carried out under conditions where the high-frequency RF power and RF frequency are 200-700 W and 10-60 MHz, respectively, and the low-frequency RF power and low-frequency RF frequency are 80-300 W and 100-500 KHz, respectively. The chamber pressure during the deposition of the second SiO₂ film can be controlled within the range of 600-1200 mT. The thickness of the second SiO₂ film can be 1000-3000 Å.

As described above, the method for preparing the current blocking layer consistent with the present disclosure involves fabricating the entire current blocking layer in two layers (a first SiO₂ film and a second SiO₂ film), through two PECVD processes. First, the first PECVD process uses high-frequency RF power, and the high-frequency RF power used in the first PECVD process is lower than that used in the second PECVD process. That is, the first SiO₂ film is prepared using a first PECVD process with low RF power and high RF frequency (HF), which avoids damage to the surface of the P-type semiconductor layer caused by high-energy particles generated by conventional low-frequency (LF) preparation processes. Then, the second PECVD process uses high-frequency and low-frequency dual-frequency RF power, and uses higher high-frequency RF power compared to the first PECVD process. That is, the second SiO₂ film is deposited on the surface of the first SiO₂ film using an in-situ high-frequency and low-frequency dual-frequency second PECVD process. The high-frequency part can obtain a higher density plasma to improve the deposition efficiency and thickness uniformity of the second SiO₂ film, and the low-frequency part can enhance the bombardment of the first SiO₂ film and second SiO₂ film, improving the film's density. Furthermore, the first SiO₂ film acts as a protective layer to prevent high-energy particles generated by the low-frequency part from directly bombarding and damaging the P-type semiconductor layer. The current blocking layer fabricated consistent with the present disclosure not only has high insulation and density but also avoids damage to the P-type semiconductor layer.

It should be noted that the reaction principle for preparing SiO₂ thin films using SiH₄, N₂O, and N₂ as reaction gases consistent with the present disclosure is as follows:

In the SiH₄ plasma, SiH₄ decomposes through collision with electrons, and the reaction equations are as follows:

$$e + {SiH}_{4} \to {SiH}_{2} + {H}_{2} + e \qquad ( 1 )$$

$$e + {SiH}_{4} \to {SiH}_{3} + H + e \qquad ( 2 )$$

$$e + {SiH}_{4} \to Si + 2 {H}_{2} + e \qquad ( 3 )$$

$$e + {SiH}_{4} \to SiH + {H}_{2} + H + e \qquad ( 4 )$$

The energy needed for each ionization reaction in equations (1)-(4) is 2.1 eV, 4.1 eV, 4.4 eV, and 5.9 eV, respectively. Due to the differences in reaction energy, the probability of each reaction (1)-(4) occurring is different. Reactions requiring lower energy are more likely to occur. The reaction is mainly (1) and a small amount of reaction (2). The presence of Si-based species is very rare. In addition, some high-energy electrons in the plasma may also undergo the following reaction:

$$e + {SiH}_{4} \to {SiH}_{2} ++ {H}_{2} + e \qquad ( 5 )$$

In addition to the above ionization reactions, secondary reactions between ions and molecules are also important:

$${SiH}_{2} ++ {SiH}_{4} \to {SiH}_{3} ++ {SiH}_{3} \qquad ( 6 )$$

Therefore, the concentration of SiH₃ neutral reactive radical is highest in the SiH₄ plasma.

In N₂O plasma, N₂O undergoes dissociation through collision with electrons, as shown in the following reactions:

$$e + {N}_{2} O \to NO + N + e \qquad ( 7 )$$

$$e + NO \to N + O + e \qquad ( 8 )$$

The formation of SiO₂ is mainly due to the reaction of O reactive radicals with SiH₂ and SiH₃ radicals, as shown in the following reactions:

$$( {SiH}_{3} ) x + ( O ) x \to {SiO}_{2} + {H}_{2} + {H}_{2} O \qquad ( 9 )$$

$$( {SiH}_{2} ) x + ( O ) x \to {SiO}_{2} + {H}_{2} + {H}_{2} O \qquad ( 10 )$$

In the plasma used in the PECVD process to prepare SiO₂ thin films using SiH₄, N₂O, and N₂, most of the species present are SiH₂ and SiH₃ radicals, while Si radicals are present in very small amounts (especially when SiH₄ is in excess). Therefore, Si—N bonds are almost never formed in the SiO₂ thin film deposition reaction. However, some Si—H bonds and Si dangling bonds will exist on the film surface, as shown in reactions (3) and (4), which can cause micro-conduction in the SiO₂ thin film, reducing the insulation of the current blocking layer.

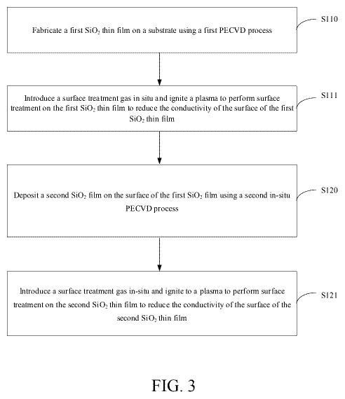

To further improve the insulation of the current blocking layer, a schematic flowchart of a method for preparing the current blocking layer provided in another embodiment of the present disclosure is shown in FIG. 3. The method for preparing the current blocking layer includes the following S111 and/or S121.

For example, in one embodiment, after S110, S111 may be included to perform surface treatment on the first SiO₂ thin film.

At S111, a surface treatment gas is introduced in situ and a plasma is ignited to perform surface treatment on the first SiO₂ thin film to reduce the conductivity of the surface of the first SiO₂ thin film.

It should be noted that the surface treatment gas is mainly used to break Si—H bonds and combine with Si dangling bonds to eliminate the micro-conduction on the surface of the first SiO₂ thin film.

For example, the surface treatment gas can be N₂O. After the first SiO₂ thin film is deposited, N₂O is introduced in-situ for plasma treatment. The N atoms introduced during the N₂O plasma treatment can break Si—H bonds and eliminate Si dangling bonds, thereby improving the insulation of the first SiO₂ thin film.

However, in the above embodiment, the N atoms can combine with the Si dangling bonds to form Si—N bonds. The presence of Si—N bonds increases the light absorption of the first SiO₂ thin film, reducing the light output efficiency of the LED chip.

Therefore, the surface treatment gas is He and O₂. He ions and O ions are generated after plasma ignition of He and O₂. He ions bombard the film surface, breaking Si—H bonds, and O ions can combine with Si dangling bonds, as well as combine with H ions and their reactive species to generate byproducts that are pumped out of the chamber. At the same time, because the molecular weight of He atoms is relatively small, the damage to the SiO₂ thin film surface is relatively small.

In one embodiment, in the surface treatment process, the RF power for ignition after in-situ introduction of He and O₂ is 100-500 W, and the RF frequency is 13.56 MHz. The flow rate of He can be 5000-8000 sccm, and the ratio of the flow rate of He to the flow rate of O₂ is 2000:1-5000:1. The reason of having low flow rate of O₂ is that O ions are highly reactive and can easily damage the SiO₂ thin film, so the flow rate should not be too high.

In one embodiment, when He and O₂ are introduced in-situ for surface treatment, the chamber pressure can be set to 800-1500 mT. Maintaining a lower chamber pressure is beneficial for He ions to break the Si—H bonds on the surface of the SiO₂ thin film.

For example, in another embodiment, S121 may be included after S120 to perform surface treatment on the second SiO₂ thin film.

At S121, the surface treatment gas is introduced in-situ and ignited to form a plasma, and surface treatment is performed on the second SiO₂ thin film to reduce the conductivity of the surface of the second SiO₂ thin film.

Specific implementation examples of S121 can be found in the embodiment of S111, and will not be repeated here.

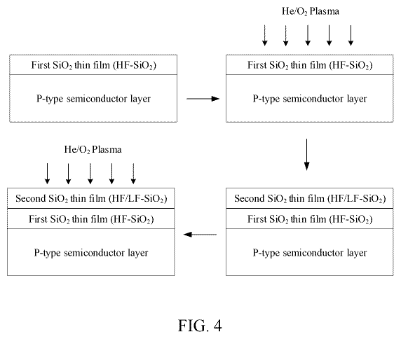

FIG. 4 is a schematic flowchart of a method for preparing a current blocking layer provided in embodiments of the present disclosure. The preparation method includes process S110 and S120, and after completing S110, S111 is performed first to perform surface treatment on the first SiO₂ thin film, then S120 is performed, and finally S121 is performed to perform surface treatment on the second SiO₂ thin film. Through surface treatment on the first SiO₂ thin film and second SiO₂ thin film separately, the micro-conductivity on the surface of the SiO₂ thin films can be eliminated, further improving the insulation of the current blocking layer. Furthermore, using He and O₂ as the surface treatment gases avoids the problem of N₂O combining with Si dangling bonds to form Si—N, which leads to low light emission efficiency.

According to the fabrication process shown in FIG. 4, a current blocking layer was prepared using N₂O as the surface treatment gas (Comparative Example), and another current blocking layer was prepared using He and O₂ as the surface treatment gases (Example). The performance of both current blocking layers was tested, and the results are shown in Table 1.

TABLE 1
Performance of current blocking layer.

| | Operating Voltage | Luminous Efficiency |
|---|---|---|
| Sample | (V) | (ml/W) |
| Comparative Example | 2.974 | 95.83 |
| Example | 3.213 | 110.26 |

The principle of the electrical performance test is as follows. Since the current blocking layer is located between the conductive layer and the P-type semiconductor layer, the presence of the current blocking layer reduces the ohmic contact area between the conductive layer and the P-type semiconductor layer. Therefore, the current blocking layer acts as a series resistor in the transmission path. Therefore, when the test current is constant, an increase in operating voltage indicates an improvement in the insulation performance of the current blocking layer.

As can be seen from the test data in Table 1, the insulation performance and luminous efficiency of the current blocking layer of the Example are superior to those of the current blocking layer of the Comparative Example.

The embodiment of the present disclosure also provides an LED chip. As shown in FIG. 1, the LED chip includes a substrate 10 and, arranged sequentially on the substrate 10 along a direction away from the substrate 10 (i.e., from bottom to top), an N-type semiconductor layer 20, a multiple quantum well layer 30, a P-type semiconductor layer 40, a conductive layer 50, a P-electrode 60 connected to the conductive layer 50, an N-electrode 70 connected to the N-type semiconductor layer 20, and a current blocking layer 80 located between the P-type semiconductor layer 40 and the conductive layer 50, directly opposite the P-electrode 60. The current blocking layer 80 is prepared using the method described in any of the above embodiments.

Reference can be made to the description of the preparation method of the current blocking layer in the above embodiments of the present disclosure for other working principles and processes of the LED chip, which will not be repeated here.

In summary, the method for preparing the current blocking layer consistent with the present disclosure involves fabricating the entire current blocking layer in two layers (a first SiO₂ film and a second SiO₂ film). Through two PECVD processes, first, a first PECVD process uses high-frequency RF power, and the high-frequency RF power used in the first PECVD process is lower than the high-frequency RF power in a second PECVD process. That is, the first SiO₂ film is prepared using a first PECVD process with low RF power and high RF frequency (HF), which avoids damage to the surface of the P-type semiconductor layer caused by high-energy particles generated by the conventional low-frequency (LF) preparation process. Then, the second PECVD process uses high-frequency-low-frequency dual-frequency RF power, and the high-frequency RF power used in the second PECVD process is higher than the high-frequency RF power in the first PECVD process. That is, the second SiO₂ film is deposited on the surface of the first SiO₂ film using an in-situ high-frequency-low-frequency dual-frequency second PECVD process. The high-frequency part can obtain a higher density plasma to improve the deposition efficiency and thickness uniformity of the second SiO₂ film, and the low-frequency part can enhance the bombardment of the SiO₂ film and second SiO₂ film, improving the film density. Furthermore, the first SiO₂ film can act as a protective layer to prevent high-energy particles generated by the low-frequency part from directly bombarding and damaging the P-type semiconductor layer. The current blocking layer fabricated in with the present disclosure not only has high insulation and high density, but also avoids damage to the P-type semiconductor layer. Further, consistent with the present disclosure, surface treatment can also be performed on the first SiO₂ film and second SiO₂ film separately to improve the insulation of the current blocking layer. Furthermore, by using He and O₂ as surface treatment gases in the present disclosure, the insulation of the current blocking layer can be improved without reducing light extraction efficiency.

The above is a detailed description of a method for preparing a current blocking layer and an LED chip consistent with the present disclosure. Specific embodiments have been used to illustrate the principles and implementation methods of the present disclosure. It should be noted that in the present disclosure, the description of each embodiment has its own focus, and reference can be made to other embodiments for any parts not described in detail in one embodiment.

The above are merely some embodiments of the present disclosure and do not therefore limit the scope of the present disclosure. Any equivalent structures or equivalent process modifications made using the content of the specification and drawings in the present disclosure, or directly or indirectly applied in other related technical fields, are similarly included within the scope of protection of the present disclosure.

What is claimed is:

1. A method for preparing a current blocking layer comprising:
fabricating a first SiO₂ thin film on a substrate using a first PECVD process; and
depositing a second SiO₂ thin film on the surface of the first SiO₂ thin film in situ using a second PECVD process;
wherein the first PECVD process uses high-frequency RF power, the second PECVD process uses high-frequency and low-frequency dual-frequency RF power, and the high-frequency RF power used in the first PECVD process is lower than the high-frequency RF power used in the second PECVD process.

2. The method according to claim 1, wherein, in the first PECVD process, the high-frequency RF power is 10-50 W, and the high-frequency RF frequency is 10-60 MHz.

3. The method according to claim 1, wherein, in the second PECVD process, the high-frequency RF power is 200-700 W, and the high-frequency RF frequency is 10-60 MHz.

4. The method according to claim 1, wherein, in the second PECVD process, the low-frequency RF power is 80-300 W, and the low-frequency RF frequency is 100-500 KHz.

5. The method according to claim 1, wherein, the reaction gases used in the first PECVD process and the second PECVD process include SiH₄, N₂O, and N₂.

6. The method according to claim 1, wherein, after depositing the second SiO₂ thin film on the surface of the first SiO₂ thin film in situ using the second PECVD process, the method further includes:
introducing a surface treatment gas in situ and igniting to generate a plasma to perform surface treatment on the second SiO₂ thin film to reduce the conductivity of the surface of the second SiO₂ thin film.

7. The method according to claim 1, wherein, after fabricating the first SiO₂ thin film on the substrate using the first PECVD process, the method further includes:
introducing a surface treatment gas in situ and igniting to generate a plasma to perform surface treatment on the first SiO₂ thin film to reduce the conductivity of the surface of the first SiO₂ thin film.

8. The method according to claim 6, wherein the surface treatment gas includes He and O₂.

9. The method according to claim 8, wherein, in the surface treatment process, the RF power for ignition is 100-500 W, and the RF frequency is 13.56 MHz.

10. The method according to claim 9, wherein the flow rate of He is 5000-8000 sccm, and the ratio of the flow rate of He to the flow rate of O₂ is 2000:1-5000:1.

11. The method according to claim 10, wherein, in the surface treatment process, the chamber pressure is 800-1500 mT.

12. The method according to claim 5, wherein, in the first PECVD process, the flow rate of SiH₄ is 5-35 sccm, the flow rate of N₂O is 500-1700 sccm, and the flow rate of N₂ is 800-2400 sccm.

13. The method according to claim 1, wherein, in the first PECVD process, the chamber pressure is 400-1200 mT.

14. The method according to claim 5, wherein, in the second PECVD process, the flow rate of SiH₄ is 10-60 sccm, the flow rate of N₂O is 1000-3000 sccm, and the flow rate of N₂ is 900-2800 sccm.

15. The method according to claim 1, wherein, in the second PECVD process, the chamber pressure is 600-1200 mT.

16. An LED chip, comprising a substrate and, sequentially disposed on the substrate in a direction away from the substrate, an N-type semiconductor layer, a multiple quantum well layer, a P-type semiconductor layer, a conductive layer, a P-electrode connected to the conductive layer, and an N-electrode connected to the N-type semiconductor layer, wherein a current blocking layer is provided between the P-type semiconductor layer and the conductive layer in the region directly opposite the P-electrode, and the current blocking layer is prepared by the preparation method for preparing a current blocking layer comprising:
fabricating a first SiO₂ thin film on a substrate using a first PECVD process; and
depositing a second SiO₂ thin film on the surface of the first SiO₂ thin film in situ using a second PECVD process;
wherein the first PECVD process uses high-frequency RF power, the second PECVD process uses high-frequency and low-frequency dual-frequency RF power, and the high-frequency RF power used in the first PECVD process is lower than the high-frequency RF power used in the second PECVD process.

17. The LED chip according to claim 16, wherein in the first PECVD process, the high-frequency RF power is 10-50 W, and the high-frequency RF frequency is 10-60 MHz.

18. The LED chip according to claim 16, wherein in the second PECVD process, the high-frequency RF power is 200-700 W, and the high-frequency RF frequency is 10-60 MHz.

19. The LED chip according to claim 16, wherein in the second PECVD process, the low-frequency RF power is 80-300 W, and the low-frequency RF frequency is 100-500 KHz.

20. The LED chip according to claim 16, wherein the reaction gases used in the first PECVD process and the second PECVD process include SiH₄, N₂O, and N₂.
